(19) United States
(12) Patent Application Publication
(10) Pub. No.: US 2016/0147144 A1
(43) Pub. Date: May 26, 2016

(54) REAGENT FOR ENHANCING GENERATION OF CHEMICAL SPECIES

(71) Applicant: TOYO GOSEI CO., LTD., Ichikawa-shi, Chiba (JP)

(72) Inventor: Satoshi Enomoto, Kamagaya-shi (Chiba-ken) (JP)

(21) Appl. No.: 14/392,348

(22) PCT Filed: Jun. 27, 2014
(86) PCT No.: PCT/JP2014/003449

§ 371 Date: Dec. 24, 2015

Related U.S. Application Data
(60) Provisional application No. 61/957,271, filed on Jun. 27, 2013.

(51) Int. Cl. G03F 7/004; G03F 7/20; G03F 7/40; C08F 220/28

(52) U.S. Cl. CPC G03F 7/0041; C08F 220/28; G03F 7/203; G03F 7/40; C08F 2220/282

(57) ABSTRACT

A reagent that enhances acid generation of a photoacid generator and composition containing such reagent is disclosed.

### CROSS-REFERENCE TO RELATED APPLICATIONS

This application is a national phase entry under 35 U.S.C. §371 of International Patent Application PCT/JP2014/003449, filed Jun. 27, 2014, designating the United States of America and published in English as International Patent Publication WO 2014/208102 A1 on Dec. 31, 2014, which claims the benefit under Article 8 of the Patent Cooperation Treaty and under 35 U.S.C. §119(e) to U.S. Provisional Patent Application Ser. No. 61/957,271, filed Jun. 27, 2013, the disclosure of which is hereby incorporated herein in its entirety by this reference.

### TECHNICAL FIELD

Several aspects of this disclosure relate to the fields of a reagent enhancing a generation of a chemical species such as acid and base. An intermediate formed from the reagent functions as a photosensitizer, which also enhances a chemical species.

### BACKGROUND

Current high-resolution lithographic processes are based on chemically amplified resists (CARs) and are used to pattern features with dimensions less than 100 nm.

A method for forming pattern features with dimensions less than 100 nm is disclosed in U.S. Pat. No. 7,851,252 (filed on Feb. 17, 2009), the contents of the entirety of which are incorporated herein by this reference.

### BRIEF SUMMARY

A reagent that enhances generation of a chemical species such as acid and a composition are disclosed in this disclosure. Typically, such reagent assists the generation of Brönsted acid or base from a precursor. Furthermore, such reagent can apply to the generation of Lewis acid and base. Typically, such reagent generates an intermediate such as a ketyl radical by having a hydrogen atom abstracted.

Ketyl radical has a reducing character and the intermediate enhances a generation of acid from the precursor. In other words, such reagent functions as an acid generation enhancer (AGE). The intermediate is converted to a product functioning as a photosensitizer. After formation of such a product, an irradiation of the product results in its excited state, which can transfer energy or an electron to the precursor or accept energy or an electron from the precursor.

The precursor generates the chemical species after receiving the energy or the electron or donating the energy or the electron. Since several AGEs are required to increase high electron donor character to enhance electron transfer to the precursor, such AGEs have at least one electron donating group on the aromatic ring such as an alkoxy group, aryloxy group, and/or hydroxyl group.

A reaction of the chemical species with a compound results in decomposition of the compound and regeneration of the chemical species. In other words, such reagent enhances generation of the chemical species in chemically amplified fashion, even if excitation is altered in a set of processes. Polymers and compositions related to several aspects of the disclosure enable processes for manufacturing devices to use a longer-wavelength light. Typically, a light, the wavelength of which is longer than or equal to 400 nm can be used for the process(es). The longer light can excite an intermediate generated from AGE if the irradiation with the longer light is carried out during the lifetime of the intermediate.

A polymer related to an aspect of this disclosure has a structure in which an AGE moiety is bonded to a chain of the polymer. The polymer can contain a precursor substituent that generates a chemical species such as acid or a reactive substituent that enables reaction with the chemical species. Since the AGE moiety can be positioned at a closer position from the precursor substituent or reactive substituent in such polymer, reactions such as those of the AGE moiety with the precursor substituent, electron or energy transfer between the AGE itself, a product or an intermediate derived from the AGE and the precursor substituent is promoted more prominently.

A polymer relating to an aspect of this disclosure includes a reagent substituent. With regard to the polymer, it is preferred that a generation of an intermediate from the reagent substituent is capable of occurring and the intermediate enhances a chemical species from a precursor.

With regard to the polymer, it is preferred that the chemical species is acid.

With regard to the polymer, it is preferred that the reagent substituent is bonded to a chain of the polymer.

With regard to the polymer, it is preferred that the polymer includes a reactive substituent that is bonded to a chain of the polymer and that is to react with the chemical species.

A polymer relating to an aspect of the disclosure includes a reagent substituent and a precursor substituent. With regard to the polymer, it is preferred that a generation of an intermediate from the reagent substituent occurs and the intermediate enhances a chemical species from the precursor.

With regard to the polymer, it is preferred that the intermediate is a ketyl radical.

With regard to the polymer, it is preferred that the intermediate is to form a product substituent.

With regard to the polymer, it is preferred that the product substituent is capable of absorbing a light of which wavelength is longer than a light that the reagent substituent absorbs.

A method for manufacturing a device utilizes any one of the polymers and also utilizes a light, the wavelength of which is longer than or equal to 400 nm for excitation of the intermediate. By excitation of the intermediate, energy transfer or electron transfer from the intermediate is enhanced.

A method for manufacturing a device includes: applying a material including a photoresist to a substrate such that a coating film including the photoresist is formed on the substrate; a first exposure of the coating film to at least one of a first electromagnetic ray and a first particle ray such that a first portion of the coating film is exposed to the at least one of the first electromagnetic ray and the first particle ray while a second portion of the coating film is not exposed to the at least one of the first electromagnetic ray and the first particle ray; and a second exposure of the coating film to a second electromagnetic ray. With regard to the method, it is preferred that the second exposure of the coating film is carried out by a light of which wavelength is equal to or longer than 400 nm.

With regard to the method, it is preferred that the method further includes removing the first portion and etching the substrate such that a third portion of the substrate on which the first portion has been present is etched.

With regard to the method, it is preferred that the first exposure of the coating film is carried out by at least one of an electron beam and a light of which wavelength is equal to or shorter than 200 nm.

With regard to the method, it is preferred that the first exposure of the coating film is carried out by a light of which wavelength is equal to or shorter than 15 nm.

With regard to the method, it is preferred that the photoresist includes a reagent that generates an intermediate that is capable of enhancing a chemical species from a precursor.

With regard to the method, it is preferred that the intermediate is excited by the light, the wavelength of which is longer than or equal to 400 nm.

With regard to the method, it is preferred that the second exposure is carried out within a period in which the intermediate generated by the first exposure exists.

A composition relating to an aspect of the disclosure includes a reagent. With regard to the reagent, it is preferred that the reagent is capable of generating an intermediate and the intermediate is capable of absorbing a light of which wavelength is longer than that of a light that the reagent is capable of absorbing.

With regard to the composition, it is preferred that the intermediate is capable of being converted to product.

With regard to the composition, it is preferred that the composition further includes a precursor that is capable of generating a chemical species by receiving an electron from at least one of the intermediate and the product.

With regard to the composition, it is preferred that the composition further includes a compound that is capable of reacting with the chemical species.

Such compositions are suitable for use in making a photoresist.

A typical example for such AGE reagents or moieties relating to several aspects of this disclosure is alcohol containing an aryl group. For example, a composition containing the reagent, a precursor that is to form a chemical species, and a compound that is to react with the chemical species, can be applied as photoresist to manufacturing of electronic devices such as semiconductor devices and electro-optical devices.

For example, after a coating film of the composition is exposed to an extreme ultraviolet (EUV) light or an electron beam (EB) in a first step, the coating film can be exposed to a light of which intensity is higher than that of the EUV light or the EB such as a UV light and a visible light. The composition can be applied to a chemically amplified reaction involved with a photoacid generator (PAG) and a resin containing a protective group such as an ester and ether group, which is to decompose by reacting with a chemical species such as acid generated from the PAG.

An oxidation reaction of aryl alcohol, which is a typical AGE, easily occurs to form a corresponding carbonyl compound. To attain the long-term stability of such AGE, the hydroxyl group of the AGE is preferably protected by a protective group such as a dialkoxy group, an alkoxycarbonyloxy group, and an ether group.

### BRIEF DESCRIPTION OF THE DRAWINGS

In the drawings, which illustrate what is currently considered to be the best mode for carrying out the disclosure:

FIG. 1 shows fabrication processes of a device such as an integrated circuit (IC) using photoresist including an AGE.

### DETAILED DESCRIPTION

### Experimental Procedures:

### Synthesis of 2,4-dimethoxy-4′-(2-vinyloxy)-ethoxy-benzophenone

2.00 g of 2,4-dihydroxy-4′-hydroxybenzophenone, 2.48 g of 2-chloroethyl vinyl ether and 3.21 g of potassium carbonate are dissolved in 12.0 g of DMF. The mixture is stirred at 110 degrees Celsius for 15 hours. Next, the mixture is cooled to 25 degrees Celsius and it is further stirred after addition of 60.0 g of water and then extracted with 24.0 g toluene and the organic phase is washed with water. Thereafter, toluene is distilled away. Thereby, 3.59 g of 2,4-dimethoxy-4′-(2-vinyloxy)-ethoxy-benzophenone is obtained.

### Synthesis of 2,4-dimethoxy-4′-(2-hydroxy)-ethoxy-benzophenone

3.59 g of 2,4-dimethoxy-4′-(2-vinyloxy)-ethoxy-benzophenone, 0.28 g of pyridinium p-toluenesulfonate and 2.1 g of water are dissolved in 18.0 g of acetone. The mixture is stirred at 35 degrees Celsius for 12 hours. Next, the mixture is further stirred after addition of 3% aqueous solution of sodium carbonate and then extracted with 28.0 g ethyl acetate and the organic phase is washed with water. Thereafter, ethyl acetate is distilled away. Thereby, 3.04 g of 2,4-dimethoxy-4′-(2-hydroxy)-ethoxy-benzophenone is obtained.

### Synthesis of (2,4-dimethoxyphenyl)-[4′-(2-hydroxy-ethyl)-phenyl)-methanol

3.0 g of 2,4-dimethoxy-4′-(2-hydroxy)-ethoxy-benzophenone and 0.01 g of potassium hydroxide are dissolved in 36.0 g of methanol. 1.13 g of sodium boron hydride is added to the methanol solution. The mixture is stirred at reflux temperature for 3 hours. Next, the mixture is added to the 240 g of water and then extracted with 40.0 g ethyl acetate and the organic phase is washed with water. Thereafter, ethyl acetate is distilled away. Thereby, 2.8 g of (2,4-dimethoxyphenyl)-[4′-(2-hydroxy-ethyl)-phenyl)]-methanol is obtained.

### Synthesis of (2,4-dimethoxyphenyl)-[4′-(2-methacryloxy-ethoxy)-phenyl]-methanol (Example 1)

2.8 g of (2,4-dimethoxyphenyl)-[4′-(2-hydroxy-ethoxy)-phenyl]-methanol and 1.4 g of methacrylic anhydride are dissolved in 20 g of tetrahydrofuran. 1.0 g of triethylamine dissolved by 3.0 g of tetrahydrofuran is added dropwise to the mixture over 10 minutes. After that, the mixture is stirred at 25 degrees Celsius for 3 hours. Next, the mixture is further stirred after addition of water and then extracted with 28 g ethyl acetate and the organic phase is washed with water. Thereafter, ethyl acetate is distilled away, and the resultant is purified by silica gel column chromatography (ethyl acetate:hexane=2:8). Thereby, 2.54 g of (2,4-dimethoxyphenyl)-[4′-(2-methacryloxy-ethoxy)-phenyl]-methanol is obtained.

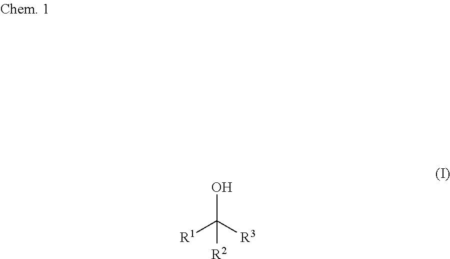

### Synthesis of 2-Methyl-acrylic acid 2-{4-[(2,4-dimethoxy-phenyl)-(1-ethoxy-ethoxy)-methyl]-phenoxy}-ethyl ester (Example 2)

1.4 g of ethyl vinyl ether and 0.06 g of pyridinium p-toluenesulfonate are dissolved in 18.0 g of methylene chloride. 1.5 g of (2,4-dimethoxyphenyl)-[4′-(2-methacryloxy-ethyl)-phenyl)-methanol dissolved by 8.0 g of methylene chloride is added dropwise to the mixture containing ethyl vinyl ether and pyridinium p-toluenesulfonate over 30 minutes after that the mixture is stirred at 25 degrees Celsius for 3 hours. Next, the mixture is further stirred after addition of 3% aqueous solution of sodium carbonate, and then the organic phase is washed with water. Thereafter, methylene chloride is distilled away, and the resultant is purified by silica gel column chromatography (ethyl acetate:hexane=5:95). Thereby, 1.31 g of 2-{4-[(2,4-dimethoxy-phenyl)-(1-ethoxy-ethoxy)-methyl]-phenoxy}-ethyl ester is obtained.

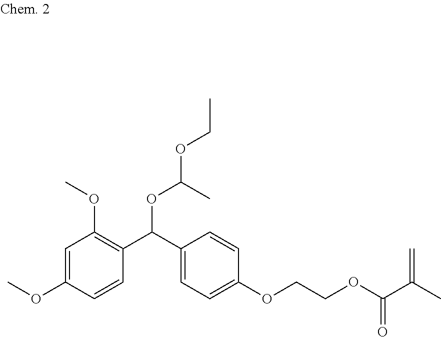 [SMILES: C=C(C)C(=O)OCCOc1ccc(C(OC(C)OCC)c2ccc(OC)cc2OC)cc1]

### Example 2

### Synthesis of 2-(2-Vinyloxy-ethoxy)-thioxanthone

3.00 g of 2-hydroxy-thioxanthone, 2.80 g of 2-chloroethyl vinyl ether and 3.63 g of potassium carbonate are dissolved in 12.0 g of DMF. The mixture is stirred at 110 degrees Celsius for 15 hours. Next, the mixture is cooled to 25 degrees Celsius and it further stirred after addition of 60.0 g of water, and then extracted with 24.0 g toluene and the organic phase is washed with water. Thereafter, toluene is distilled away. Thereby, 3.69 g of 2-(2-Vinyloxy-ethoxy)-thioxanthone is obtained.

### Synthesis of 2-(2-Hydroxy-ethoxy)-thioxanthone

3.69 g of 2-(2-Vinyloxy-ethoxy)-thioxanthone, 0.31 g of pyridinium p-toluenesulfonate and 2.2 g of water are dissolved in 18.5 g of acetone. The mixture is stirred at 35 degrees Celsius for 12 hours. Next, the mixture is further stirred after addition of 3% aqueous solution of sodium carbonate and then extracted with 28.0 g ethyl acetate and the organic phase is washed with water. Thereafter, ethyl acetate is distilled away. Thereby, 3.10 g of 2-(2-Hydroxy-ethoxy)-thioxanthone is obtained.

### Synthesis of 2-(2-Hydroxy-ethoxy)-9H-thioxanthen-9-ol

3.0 g of 2-(2-Hydroxy-ethoxy)-thioxanthone and 0.01 g of potassium hydroxide are dissolved in 36.0 g of methanol. 1.25 g of sodium boron hydride is added to the methanol solution. The mixture is stirred at reflux temperature for 3 hours. Next, the mixture is added to the 240 g of water, and then extracted with 40.0 g ethyl acetate and the organic phase is washed with water. Thereafter, ethyl acetate is distilled away. Thereby, 2.8 g of 2-(2-Hydroxy-ethoxy)-9H-thioxanthen-9-ol is obtained.

### Synthesis of 2-methyl-acrylic acid 2-(9-hydroxy-9H-thioxanthen-2-yloxy)-ethyl ester (Example 3)

2.8 g of 2-(2-Hydroxy-ethoxy)-9H-thioxanthen-9-ol and 1.6 g of methacrylic anhydride are dissolved in 20 g of tetrahydrofuran. 1.1 g of triethylamine dissolved by 3.0 g of tetrahydrofuran is added dropwise to the mixture over 10 minutes, and then, the mixture is stirred at 25 degrees Celsius for 3 hours. Next, the mixture is further stirred after addition of water and then extracted with 28 g ethyl acetate and the organic phase is washed with water. Thereafter, ethyl acetate is distilled away, and the resultant are purified by silica gel column chromatography (ethyl acetate:hexane=2:8). Thereby, 2.59 g of 2-Methyl-acrylic acid 2-(9-hydroxy-9H-thioxanthen-2-yloxy)-ethyl ester is obtained.

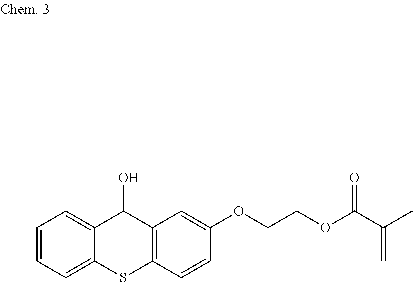 [SMILES: C=C(C)C(=O)OCCOc1ccc2c(c1)C(O)c1ccccc1S2]

### Example 3

A solution containing 0.82 g of (2,4-dimethoxyphenyl)-[4′-(2-methacryloxy-ethoxy)-phenyl]-methanol, 3.0 g of α-methacryloyloxy-γ-butylolactone, 2.6 g of 2-methyladamantane-2-methacrylate, 3.1 g of 3-hydroxyadamantane-1-methacrylate, 0.20 g of butyl mercaptane, 0.51 g of dimethyl-2,2′-azobis(2-methylpropionate) and 11.2 g of tetrahydrofuran is prepared. Butyl mercaptane is converted into a corresponding radical that adjusts the polymer chain length. The prepared solution is added dropwise for 4 hours to 8.0 g of tetrahydrofuran placed in flask with stirring and boiling. After the addition of the prepared solution, the mixture is heated to reflux for 2 hours and cooled to room temperature. Addition of the mixture by drops to a mixed liquid containing 110 g of hexane and 11 g of tetrahydrofuran with vigorously stirring precipitates the copolymer. The copolymer is isolated by filtration. Purification of the copolymer is carried out by vacuum drying following two washings by 40 g of hexane and, thereby, 6.9 g of white powder of the copolymer (Resin A) is obtained.

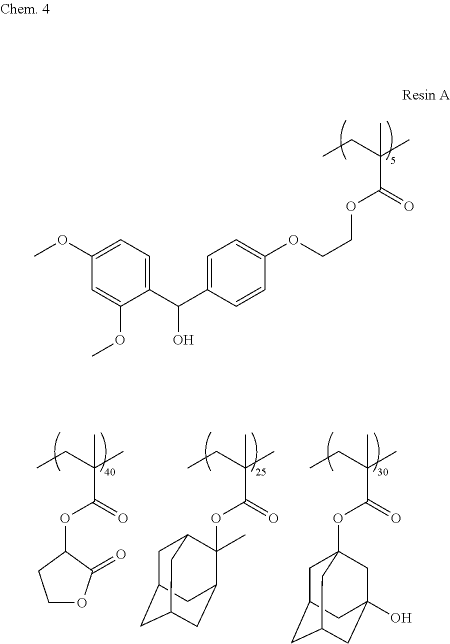

A solution containing 0.98 g of 2-{4-[(2,4-dimethoxy-phenyl)-(1-ethoxy-ethoxy)-methyl]-phenoxy}-ethyl ester, 3.0 g of α-methacryloyloxy-γ-butylolactone, 2.6 g of 2-methyladamantane-2-methacrylate, 3.1 g of 3-hydroxyadamantane-1-methacrylate, 0.20 g of butyl mercaptane, 0.51 g of dimethyl-2,2′-azobis(2-methylpropionate) and 11.2 g of tetrahydrofuran is prepared. The prepared solution is added dropwise for 4 hours to 8.0 g of tetrahydrofuran placed in flask with stirring and boiling. After the addition of the prepared solution, the mixture is heated to reflux for 2 hours and cooled to room temperature. Addition of the mixture by drops to a mixed liquid containing 110 g of hexane and 11 g of tetrahydrofuran with vigorously stirring precipitates the copolymer. The copolymer is isolated by filtration. Purification of the copolymer is carried out by vacuum drying following two washings by 40 g of hexane and, thereby, 7.1 g of white powder of the copolymer (Resin B) is obtained. Since the diarylmethanol moiety functioning as an AGE in Resin B is protected by a protecting group, Resin B has a long-term stability relatively higher than Resin A. In the meantime, the diarylmethanol moiety develops the AGE function by having the protecting group decomposed by acid generated from the PAG.

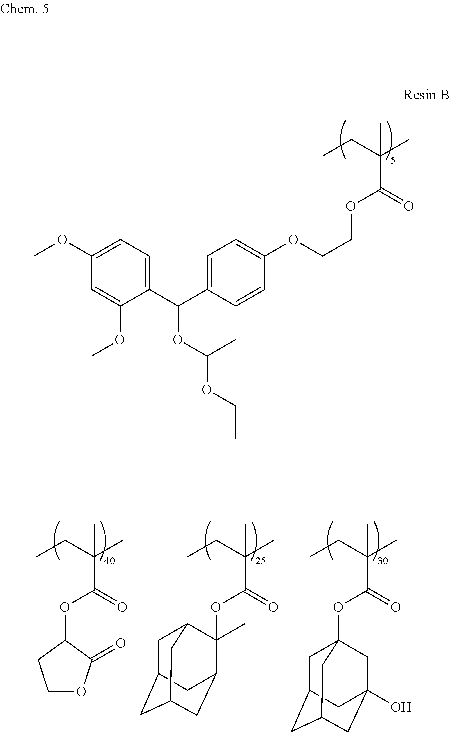

A solution containing 0.76 g of 2-Methyl-acrylic acid 2-(9-hydroxy-9H-thioxanthen-2-yloxy)-ethyl ester, 3.0 g of α-methacryloyloxy-γ-butylolactone, 2.6 g of 2-methyladamantane-2-methacrylate, 3.1 g of 3-hydroxyadamantane-1-methacrylate, 0.20 g of butyl mercaptane, 0.51 g of dimethyl-2,2′-azobis(2-methylpropionate) and 11.2 g of tetrahydrofuran is prepared. The prepared solution is added dropwise for 4 hours to 8.0 g of tetrahydrofuran placed in flask with stirring and boiling. After the addition of the prepared solution, the mixture is heated to reflux for 2 hours and cooled to room temperature. Addition of the mixture by drops to a mixed liquid containing 110 g of hexane and 11 g of tetrahydrofuran with vigorous stirring precipitates the copolymer. The copolymer is isolated by filtration. Purification of the copolymer is carried out by vacuum drying following two washings by 40 g of hexane and, thereby, 5.1 g of white powder of the copolymer is obtained.

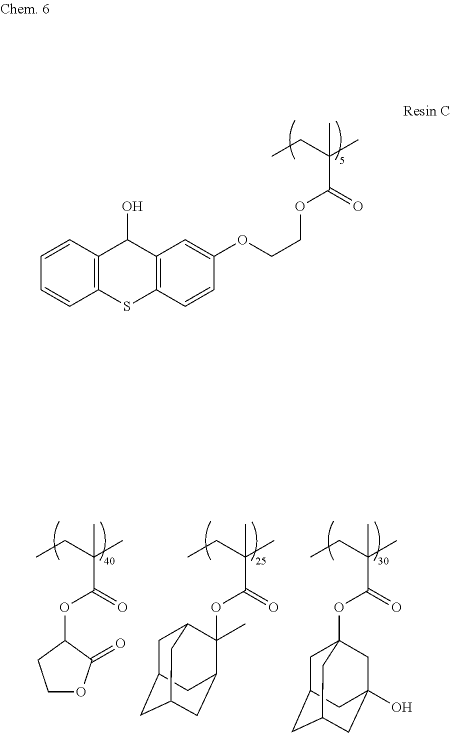

A solution containing 0.98 g of (2,4-dimethoxyphenyl)-[4′-(2-methacryloxy-ethoxy)-phenyl)-methanol, 3.0 g of α-methacryloyloxy-γ-butylolactone, 2.6 g of 2-methyladamantane-2-methacrylate, 3.1 g of 3-hydroxyadamantane-1-methacrylate, 1.1 g of 5-phenyl-dibenzothiophenium 1,1-difluoro-2-(2-methyl-acryloyloxy)-ethanesulfonate, 0.20 g of butyl mercaptane, 0.51 g of dimethyl-2,2′-azobis(2-methylpropionate) and 12.2 g of tetrahydrofuran is prepared. 5-phenyl-dibenzothiophenium 1,1-difluoro-2-(2-methyl-acryloyloxy)-ethanesulfonate functions as a PAG moiety. The prepared solution is added dropwise for 4 hours to 8.0 g of tetrahydrofuran placed in flask with stirring and boiling. After the addition of the prepared solution, the mixture is heated to reflux for 2 hours and cooled to room temperature. Addition of the mixture by drops to a mixed liquid containing 110 g of hexane and 11 g of tetrahydrofuran with vigorously stirring precipitates the copolymer. The copolymer is isolated by filtration. Purification of the copolymer is carried out by vacuum drying following two washings by 40 g of hexane and two washings by methanol. Thereby, 5.7 g of white powder of the copolymer (Resin D) is obtained.

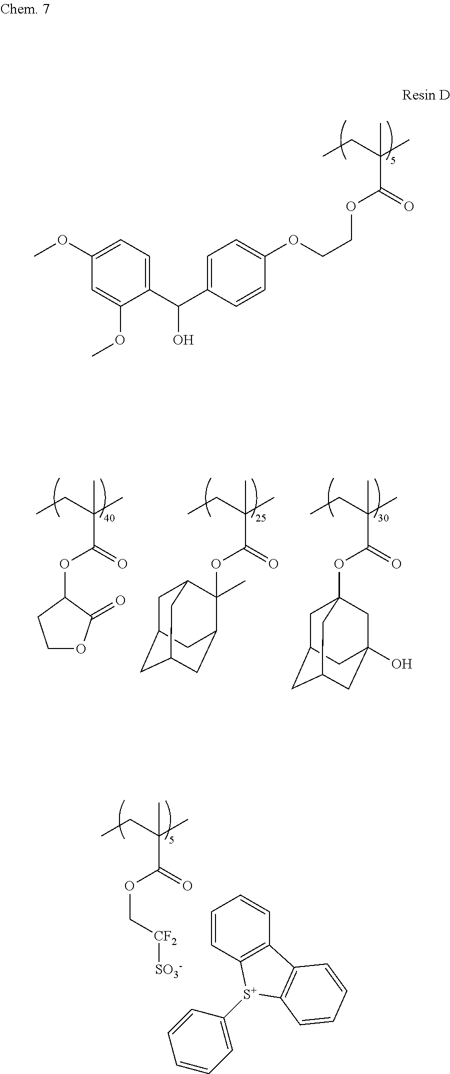

Preparation of Samples for Evaluation (the “Evaluation Sample”)

Evaluation Samples 1-3 are prepared by dissolving 24.9 mg of diphenyliodonium nonafluorobutanesulfonate (DPI-PFBS) as a photoacid generator (PAG) and 600 mg of Resins A, B and C and in 8000 mg of cyclohexanone, respectively, while Evaluation Sample 4 is prepared by dissolving 600 mg of Resin D in 8000 mg of cyclohexanone.

Evaluation of Sensitivity-1

Before applying the Evaluation Samples to an Si wafer, hexamethyldisilazane (HMDS, Tokyo Chemical Industry) is spin-coated at 2000 rpm for 20 seconds on the surface of Si wafer and baked at 110 degrees Celsius for 1 minute. Then, each of the Evaluation Samples is spin-coated on the surface of the Si wafer that has been treated with HMDS at 4000 rpm for 20 seconds to form a coating film.

The prebake of the coating film is performed at 110 degrees Celsius for 60 seconds. Then, the coating film is exposed to electron beam (EB) output from an EB radiation source. After the EB exposure, an irradiation of the coating film with a UV light is carried out at an ambient condition. After that, the UV light exposure, a post-exposure-bake (PEB) is carried out at 100 degrees Celsius for 60 seconds. The coating film is developed with NMD-3 (tetra-methyl ammonium hydroxide 2.38%, Tokyo Ohka Kogyo) for 60 seconds at 25 degrees Celsius and rinsed with deionized water for 10 seconds. The thickness of the coating film measured using film thickness measurement tool is approximately 150 nm.

A sensitivity (E₀ sensitivity) is evaluated by measuring the doses to form a pattern constituted by 2-micrometer lines where the thickness of the coating film is not zero and 2-micrometer spaces where the thickness of the coating film is zero using 30 keV electron beam lithography (EBL) system JSM-6500F (JEOL, beam current: 12.5 pA, <1E-4 Pa) with Beam Draw (Tokyo Technology) and the UV exposures using FL-6BL (bright line is mainly from 320 nm to 380 nm, Toshiba).

Even if the UV exposure is carried out without a mask, 2-micrometer spaces are formed in the parts of the coating film that has been exposed to the EB source. This indicates that a product functioning as a photosensitizer for the UV light is generated in the parts exposed to the EB exposure because the PAGs and the PAG moiety used for the evaluation exhibit little absorbance in a rage from 320 nm to 380 nm.

Table 1 shows the dose sizes corresponding to E₀ sensitivities measured for the Evaluation Samples 1 and 2. Table 1 shows that the doses of the EB exposure decreases with increase of the doses of the UV light exposure. Ketyl radicals are formed from the diarylmethanol moieties of Evaluation Samples 1-3 by the EB exposure and the ketyl radicals are oxidized to form corresponding ketones that can be excited by the UV light and function as sensitizer to enhance acid generation of the PAG.

TABLE 1
The doses for E₀ light by an EB and UV
exposure for the Evaluation Samples.

Total dose for E₀

| | EB dose | UV dose |
|---|---|---|
| | [μC/cm²] | [mJ/cm²] |
| Evaluation | 23.0 | 0 |
| Sample 1 | 15.0 | 560 |
| | 5.0 | 3350 |
| Evaluation | 23.0 | 0 |
| Sample 2 | 15.0 | 560 |
| | 5.0 | 3350 |
| Evaluation | 22.0 | 0 |
| Sample 3 | 10.0 | 560 |
| | 3.8 | 1680 |

Evaluation of Sensitivity-2

Before applying the Evaluation Samples to an Si wafer, hexamethyldisilazane (HMDS, Tokyo Chemical Industry) is spin-coated at 2000 rpm for 20 seconds on the surface of an Si wafer and baked at 110 degrees Celsius for 1 minute. Then, each of the Evaluation Samples is spin-coated on the surface of the Si wafer that has been treated with HMDS at 4000 rpm for 20 seconds to form a coating film. The prebake of the coating film is performed at 110 degrees Celsius for 60 seconds. Then, the coating film is exposed to 100 keV EB output from EB radiation source through the 2 mm line and space patterned mask.

After the EB exposure, the coating film is exposed white LED light within delay of several seconds from the EB exposure. Next, an irradiation of the coating film with a UV light is carried out at an ambient condition. After the UV light exposure, a post-exposure bake (PEB) is carried out at 100 degrees Celsius for 60 seconds. The coating film is developed with NMD-3 (tetra-methyl ammonium hydroxide 2.38%, Tokyo Ohka Kogyo) for 60 seconds at 25 degrees Celsius and rinsed with deionized water for 10 seconds. The thickness of the coating film measured using film thickness measurement tool is approximately 150 nm.

A sensitivity (E₀ sensitivity) is evaluated by measuring the doses to form a pattern constituted by 2-micrometer lines where the thickness of the coating film is not zero and 2-micrometer spaces where the thickness of the coating film is zero by using EB-Engine® (Hamamatsu Photonics).

The exposures to the white LED light (bright line is mainly from 400 nm to 700 nm) are carried out under vacuum condition. The UV light has bright lines mainly from 320 nm to 380 nm (FL-6BL Toshiba) and the UV light exposure is carried out under ambient condition.

Even if the UV exposure is carried out without a mask, 2-micrometer spaces are formed in the parts of the coating film that has been exposed to the EB and LED. This indicates that a product functioning as a photosensitizer for the UV light is generated in the parts exposed to the LED light after EB exposure. On the other hand, 2-micrometer spaces are not formed by UV exposure without LED light exposure after EB exposure. The results indicate that the reduction of sulfonium cations of the PAGs and the PAG moiety by excited state of a ketyl radical formed from (2,4-dimethoxyphenyl)-[4′-(2-methacryloxy-ethyl)-phenyl)-methanol by the white LED light exposure is relatively high while the efficiency of reduction of the sulfonium cations by the ground state of the ketyl radical is low. In other words, the excitation of ketyl radical by a visible light exposure is considered to enhance its reducing character.

Table 2 shows the dose sizes corresponding to E₀ sensitivities measured for the Evaluation Sample 4. Table 2 indicates that the doses of the EB exposure decreases with increase of the doses of the UV light exposure after the LED light exposure. This indicates that such transient excitation by a longer-wavelength light produces an excited state of the ketyl radical, which enhances acid generation of the PAG moiety.

TABLE 2
The doses for E₀ light by an EB, LED and
UV exposure for the Evaluation Sample 3.

| | Total doses for E₀ | | |
|---|---|---|---|
| | EB dose | LED dose | UV dose |
| | [μC/cm²] | [lm · s] | [mJ/cm²] |
| Evaluation | 28 | 0 | 0 |
| Sample 4 | 28 | 0 | 3350 |
| | 14 | 1520 | 3350 |

A photoresist including any one of Evaluation Samples 1-4 can be applied to fabrication processes of a device such as an integrated circuit (IC).

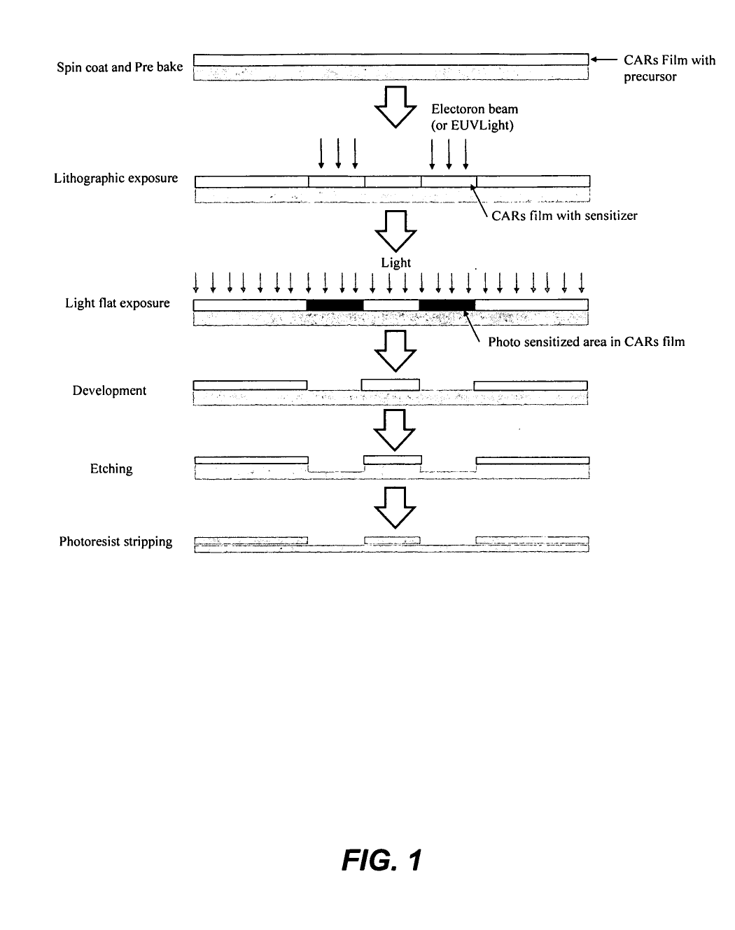

FIG. 1 shows fabrication processes of a device such as an integrated circuit (IC) using the photoresist.

A silicon wafer is provided. The surface of silicon wafer is oxidized by heating the silicon wafer in the presence of oxygen gas.

The photoresist is applied to the surface of an Si wafer by spin coating to form a coating film. The coating film is prebaked.

An irradiation of the coating film with an EUV light through a mask is carried out after prebake of the Si wafer. The deprotection reaction of the coating film is induced by acid generated by photoreaction of the photoacid generator and assistance by the AGE moiety.

An irradiation of the coating film with a UV or visible light may be carried out within a period in which an intermediate generated from the EUV light lives to improve the reaction efficiency after the irradiation of the coating film with the EUV light.

An electron beam can be used instead of the EUV light.

After the EUV irradiation of the coating film, an irradiation of the coating film with a light of which wavelength is equal to or longer than 300 nm is carried out without any mask.

Development of the coating film that has been irradiated with the EUV light and the light of which wavelength is equal to or longer than 300 nm is performed after the prebake.

The coating film and the silicon wafer are exposed to plasma. After that, the remaining film is removed.

An electronic device such as an integrated circuit is fabricated utilizing the processes shown in FIG. 1. The deterioration of the device due to the irradiation with a light is suppressed compared to existing photoresists since times for irradiation of the coating film is shortened.

1. A polymer, comprising:
a chain of the polymer; and
a reagent substituent bonded to the chain of the polymer, wherein:
a generation of an intermediate from the reagent substituent occurs by an exposure to light having a wavelength shorter than or equal to 15 nm;
the intermediate enhances a chemical species from a precursor; and
the intermediate is for forming a product substituent including a carbonyl substituent.

2. The polymer according to claim 1, wherein the chemical species is acid.

3. (canceled)

4. The polymer according to claim 1, further comprising:
a reactive substituent that is bonded to the chain of the polymer and that is to react with the chemical species.

5. The polymer of claim 1, further comprising:
a precursor substituent bonded to the chain of the polymer, wherein:
the intermediate enhances the chemical species from the precursor substituent.

6. The polymer according to claim 1, wherein the intermediate is a ketyl radical.

7. (canceled)

8. The polymer according to claim 7, wherein the product substituent is capable of absorbing a light having a wavelength longer than a light that the reagent substituent absorbs, and
wherein the light that the product substituent absorbs is between 320 nm to 380 nm.

9. (canceled)

10. A method for manufacturing a device, the method comprising:
applying a material including a photoresist comprising the polymer of claim 1 to a substrate such that a coating film including the photoresist is formed on the substrate; and
a first exposure of the coating film to at least one of a first electromagnetic ray and a first particle ray such that a first portion of the coating film is exposed to the at least one of the first electromagnetic ray and the first particle ray while a second portion of the coating film is not exposed to the at least one of the first electromagnetic ray and the first particle ray; and
a second exposure of the coating film with a second electromagnetic ray.

11. The method according to claim 10, further comprising:
removing the first portion; and
etching the substrate such that a third portion of the substrate on which the first portion has been present is etched.

12. (canceled)

13. The method according to claim 10, wherein the first exposure of the coating film is carried out by a light having a wavelength shorter than or equal to 15 nm.

14. (canceled)

15. The method according to claim 14, wherein the second exposure of the coating film is carried out by a light having a wavelength longer than or equal to 400 nm.

16. The method according to claim 15, wherein the second exposure is carried out within a period in which the intermediate generated from the first exposure exists.

17. A composition, comprising:
the polymer of claim 1.

18.-20. (canceled)

21. The polymer of claim 1, wherein exposure of the intermediate to a light of a wavelength longer than or equal to 400 nm causes excitation of the intermediate.
